(19) United States
(12) Patent Application Publication
(10) Pub. No.: US 2026/0353607 A1
(43) Pub. Date: Nov. 5, 2026

(54) COOLING SYSTEM AND METHOD, WITH DOUBLE STRUCTURE COLD PLATE

(71) Applicant: SCS GLOBAL COMPANY, Seattle, WA (US)

(72) Inventor: ANDREW JAVIER ERPELDING, PORTLAND, OR (US)

(73) Assignee: SCS GLOBAL COMPANY, Seattle, WA (US)

(21) Appl. No.: 19/195,707

(22) Filed: Apr. 30, 2025

(51) Int. Cl. H05K 7/20; H05K 1/02

(52) U.S. Cl. CPC H05K 7/20336; H05K 1/0203; H05K 7/20218; H05K 7/20445; H05K 7/20509

(57) ABSTRACT

The present disclosure relates to a cooling system including a first heat transfer section comprising a liquid, wherein the first heat transfer section comprises a liquid outlet and a liquid inlet, and a second heat transfer section comprising refrigerant which is a mixture of liquid refrigerant and gas refrigerant, wherein the second heat transfer section has a closed structure. The liquid refrigerant is configured to be phase-changed to the gas refrigerant by exchanging heat with a die, and the gas refrigerant is configured to be phase-changed to the liquid refrigerant by exchanging heat with the liquid of the first heat transfer section.

### FIELD

The present application relates to cooling system and method, with double structure cold plate, for cooling computer components.

### BACKGROUND

Removing waste heat generated by electronic components is critical for ensuring performance of computing systems. Various types of computer coolers have been developed based on different cooling mechanisms. In general, existing coolers are either air-based or liquid-based. Between the two, liquid-based cooling provides advantages over air-based cooling due to better thermophysical properties, such as the higher thermal conductivity, density and specific heat capacity of liquid compared with air. Therefore, liquid-based cooling can provide a more compact cooling solution with higher cooling effectiveness and lower power consumption.

Some relatively high-powered and computational expensive components such as central processing units (CPUs) and graphics processing units (GPUs) can generate a large amount of heat during operation and thus may require targeted cooling. A CPU forms part of a CPU card and a GPU forms part of a graphics card, both are printed circuit board packed with a large number of electronic across a limited board surface area. The components are further electrically connected using conductive tracks, pads, and other features. Taking a motherboard as an example; it typically comprises at least one CPU chip, various memory chips, memory controllers, input/output systems, and interface connectors, etc. Therefore, it can be challenging to mount a designated cooler for targeted cooling of a specific component on a densely packed computer board or card to achieve the desired cooling effectiveness.

A Power Usage Effectiveness (PUE) is a widely used metric that measures the energy efficiency of a data center. The PUE is a value obtained by dividing the total facility energy consumption of the data center by the power consumption of the IT equipment. The theoretical minimum PUE is 1.0, meaning all energy is used by IT equipment and none is wasted on overhead. In practice, achieving a PUE of exactly 1.0 is nearly impossible because some energy will always be used for cooling, lighting, and other support systems.

The largest portion of energy consumption in data centers is a cooling system. About 94% of data center problems are related to its cooling systems. This is because data centers must maintain stable temperatures while dealing with continuously increasing IT loads.

The PUE value varies greatly depending on the cooling method. As shown in FIG. 1, the PUE values of the conventional cooling methods is as follows.
Room-Level Cooling (CRAC/CRAH): Approximately 1.7
Row-Level Cooling (In-Row): Approximately 1.5
Rack-Level Cooling (RDHx): Approximately 1.3
U-Level Cooling (Cold Plate): Approximately 1.2
System-Level Cooling (Impression): Approximately 1.05

Among the above, the Immersion cooling method provides the lowest PUE, but it is difficult to apply it in a general data center environment due to space constraints, high equipment weight, and chemical reaction problems of insulating oil. On the other hand, the air cooling method is structurally limited and is not suitable for high-performance IT equipment.

Therefore, there is a need for a novel cooling technology that can compensate for the shortcomings of the existing method while maximizing cooling efficiency. The present disclosure addresses at least some of the issues that are present in the existing cooling systems.

### SUMMARY

The present disclosure provides a cooling technology, which can be used for a data center. The present disclosure provides a dual-structure cold plate cooling system in which cooling water and a refrigerant are combined to achieve higher energy efficiency. Accordingly, the power usage efficiency (PUE) of the data center may be lowered to 1.15, and the limitations of the existing cooling system may be overcome.

According to an embodiment of the present disclosure, a cooling system includes a first heat transfer section comprising a liquid, wherein the first heat transfer section comprises a liquid outlet and a liquid inlet, and a second heat transfer section comprising refrigerant which is a mixture of liquid refrigerant and gas refrigerant, wherein the second heat transfer section has a closed structure. The liquid refrigerant is configured to be phase-changed to the gas refrigerant by exchanging heat with a die, and the gas refrigerant is configured to be phase-changed to the liquid refrigerant by exchanging heat with the liquid of the first heat transfer section.

According to another embodiment of the present disclosure, a cooling method includes circulating a liquid through a liquid outlet and a liquid inlet of the first heat transfer section from outside the first heat transfer section to inside first heat transfer section, circulating the refrigerant, which is a mixture of liquid refrigerant and gas refrigerant, only inside the second heat transfer section having a closed structure, performing a first phase-change from the liquid refrigerant to the gas refrigerant by exchanging heat with the die, and performing a second phase-change from the gas refrigerant to the liquid refrigerant by exchanging heat with the liquid of the first heat transfer section.

The system and the method according to the present disclosure facilitate improved performance of heat exchange for effective cooling of high-powered and computational expensive components such as CPUs and GPUs.

### BRIEF DESCRIPTION OF THE DRAWINGS

Unless specified otherwise, the accompanying drawings illustrate aspects of the innovative subject matter described herein. Referring to the drawings, wherein like reference numerals indicate similar parts throughout the several views, several examples of systems incorporating aspects of the presently disclosed principles are illustrated by way of example, and not by way of limitation, wherein:

FIG. 1 shows Power Usage Effectiveness (PUE) values of the conventional cooling methods and the PUE value of a cooling system according to embodiments of the present disclosure;

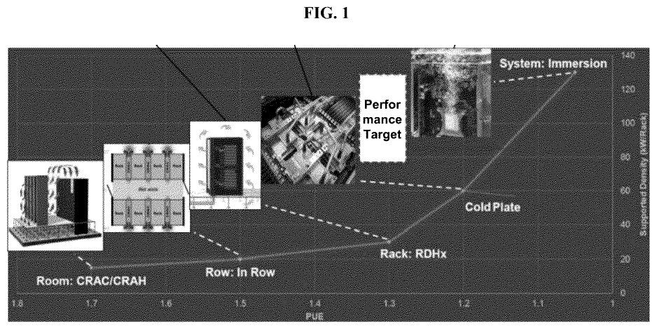

FIG. 2 is a schematic showing the cooling system according to some embodiments of the present disclosure; and

FIG. 3 is a schematic showing a cooling method according to some embodiments of the present disclosure.

### DETAILED DESCRIPTION

The present invention will now be exemplified with reference to the accompanying drawings.

The term “data center” loosely refers to a physical location housing one or more servers. In some instances, a data center can simply comprise an unobtrusive corner in a small office. In other instances, a data center can comprise several large, warehouse-sized buildings enclosing tens of thousands of square feet and housing thousands of servers. Regardless of their size, data centers and the servers they house consume vast amounts of electrical power. Although operating servers account for a major portion of the power consumed by a given data center, cooling the servers using conventional approaches accounts for another significant portion of the consumed power.

The following discussion provides many exemplary embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

For simplicity and clarity of illustration, reference numerals may be repeated among the figures to indicate corresponding or analogous elements. Numerous details are set forth to provide an understanding of the examples described herein. The examples may be practiced without these details. In other instances, well-known methods, procedures, and components are not described in detail to avoid obscuring the examples described. The description is not to be considered as limited to the scope of the examples described herein.

The words comprises/comprising when used in this specification are to specify the presence of stated features, integers, steps or components but does not preclude the presence or addition of one or more other features, integers, steps, components or groups thereof.

The present disclosure provides a cooling system having a dual structure, which uses a liquid and a refrigerant to lower the PUE of the data center to 1.15 which is an improvement over the existing cold plate method, which is 1.2 PUE.

The conventional cold plate method transfers heat directly through a cooling plate attached to the IT equipment, but the cooling system according to the present disclosure has following characteristics.
1. High heat transfer performance optimized for high-heat IT equipment
   High-performance NVIDIA GPU chips that generate more than 1 kW of heat
   Reliable cooling performance even in high heat environments that traditional air cooling methods cannot handle
2. Prevent chip damage at high heat transfer rates
   Provides faster heat transfer rates than before to prevent damage caused by overheating of the chip-die
   Ensure the reliability of high-heat IT equipment to extend the life of the equipment
3. Different cooling structure

The dual structure cold plate cooling system proposed by this invention includes the following characteristics to provide improved heat exchange performance compared to the existing cold plate method.
(i) Closed two-phase refrigerant circulation system
   (a) Apply the method in which refrigerant transfers heat quickly between liquid and gas states
   (b) Provides higher heat transfer rates than conventional coolant methods
(ii) High heat capacity transfer using high liquid flow
   (a) Use cooling liquids with high specific heat to deliver more heat effectively
   (b) Improved heat exchange efficiency over traditional single coolant method
(iii) Dual-structured Cold Plate Design
   (a) Optimized heat transfer performance through double-layer cooling plate design
   (b) Provides more uniform cooling than traditional single-cold plate methods

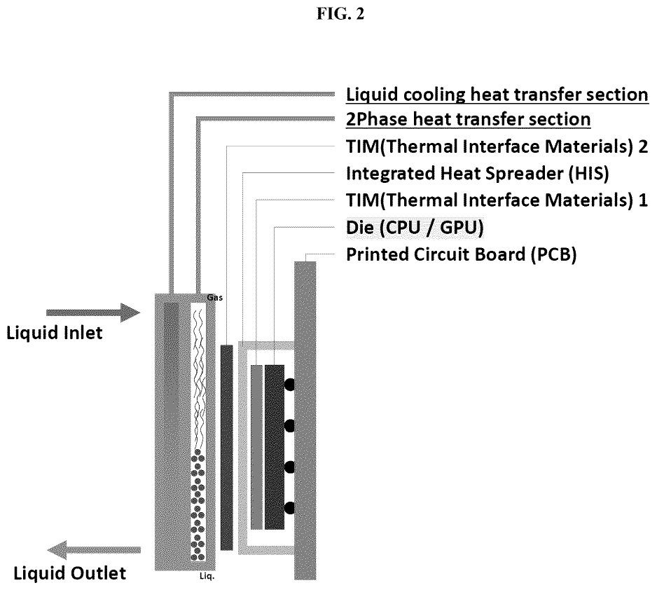

FIG. 2 is a schematic showing the cooling system according to some embodiments of the present disclosure.

In some embodiments according to the present disclosure, the cooling system includes a first heat transfer section and a second heat transfer section.

A liquid is used in the first heat transfer section. The liquid may include deionized water, ethylene glycol, and propylene glycol.

The first heat transfer section has at least one liquid outlet and at least one liquid inlet. The at least one liquid outlet and the at least one liquid inlet are connected with outside the first heat transfer section. Thus, the liquid inflows to the first heat transfer section via the at least one liquid inlet, and the liquid outflows from the first heat transfer section via the at least one liquid outlet. That is, the liquid circulates inside and outside the first heat transfer section. With this, the liquid flows through the first heat transfer section, and as it moves, it absorbs heat from the second heat transfer section via conduction through a wall between the first heat transfer section and the second heat transfer section.

A refrigerant is used in the second heat transfer section. The refrigerant is a mixture of liquid refrigerant and gas refrigerant. The second heat transfer section has a closed structure. The refrigerant circulates only inside the second heat transfer section.

The liquid refrigerant is phase-changed to the gas refrigerant by exchanging heat with a die, and the gas refrigerant is phase-changed to the liquid refrigerant by exchanging heat with the liquid of the first heat transfer section. As the refrigerant moves and is phase-changed, the refrigerant exchanges heat with the first heat transfer section via conduction through the wall between the first heat transfer section and the second heat transfer section, and also with the die, which is a silicon material on which a processor is fabricated. That is, the refrigerant transfers heat from the processor to the first heat transfer section.

Refrigerant materials include natural refrigerants and synthetic refrigerants. The natural refrigerants include substances found in nature such as ammonia (NH₃, R717), carbon dioxide (CO₂, R744), and hydrocarbons (like propane, R290). The synthetic refrigerants include chlorofluorocarbons (CFCs), hydrochlorofluorocarbons (HCFCs), hydrofluorocarbons (HFCs), hydrofluoroolefins (HFOs): Fourth-generation refrigerants like R1234yf, designed to have very low GWP and no ozone depletion.

In some embodiments according to the present disclosure, the cooling system further includes a printed circuit board (PCB) contacting to a first side the die, a first thermal interface material (TIM) placed on a second side of the die, an integrated heat spreader encompassing the PCB, the die, and the first TIM, and a second TIM placed on the integrated heat spreader. The second heat transfer section is contacting to the second TIM. The first TIM and the second TIM may include thermal grease/paste, thermal pads, thermal tape, phase-change materials, metal TIMs, and graphite-based materials.

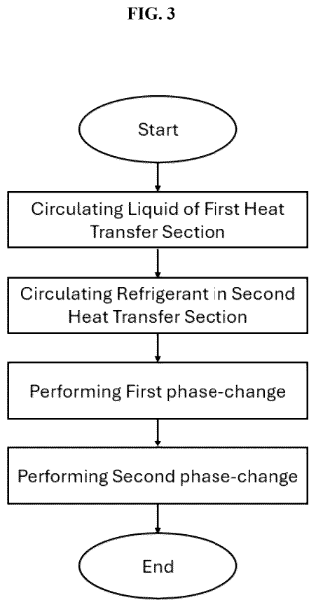

FIG. 3 is a schematic showing a cooling method according to some embodiments of the present disclosure.

In some embodiments according to the present disclosure, the cooling method includes a step of circulating a liquid through a liquid outlet and a liquid inlet of the first heat transfer section from outside the first heat transfer section to inside first heat transfer section, a step of circulating a refrigerant, which is a mixture of liquid refrigerant and gas refrigerant, only inside the second heat transfer section having a closed structure, a step of performing a first phase-change from the liquid refrigerant to the gas refrigerant by exchanging heat with the die, and a step of performing a second phase-change from the gas refrigerant to the liquid refrigerant by exchanging heat with the liquid of the first heat transfer section.

The refrigerant absorbs heat from the environment as it evaporates (liquid to gas) in the second heat transfer section, cooling the surrounding area. The gas refrigerant is then compressed, raising its temperature and pressure. In the second heat transfer section, the refrigerant releases its absorbed heat to the outside as it condenses (gas to liquid). These changes provide efficient heat transfer and temperature control.

The cooling system of the present disclosure provides the following effects compared to the conventional cooling methods for the data centers.
1. Reduce energy savings and operating costs
   (i) Increase PUE to 1.15 with 4% additional savings over traditional cold plate methods (PUE 1.2)
   (ii) Reduce operational costs by reducing power consumption in the data center
2. Optimized for high-heat IT equipment
   (i) 1 kW or more high-power GPUs and AI servers can be cooled
   (ii) Chip overheat prevention allows data center equipment to extend its life
3. Easy to install and maintain
   (i) Unlike the Immersion method, it can utilize existing data center infrastructure, making it easy to apply
   (ii) Can be managed without additional problems such as insulation oil treatment during maintenance
4. Environmentally friendly design
   (i) Environmentally friendly cooling using closed circulation system of refrigerant
   (ii) Reducing carbon emissions through energy conservation

Directions and references (e.g., up, down, top, bottom, left, right, rearward, forward, etc.) may be used to facilitate discussion of the drawings but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by references in its entirety for all purposes.

The principles described above in connection with any particular example can be combined with the principles described in connection with any one or more of the other examples. Accordingly, this detailed description shall not be construed in a limiting sense, and following a review of this disclosure, those of ordinary skill in the art will appreciate the wide variety of fluid heat exchange systems that can be devised using the various concepts described herein. Moreover, those of ordinary skill in the art will appreciate that the exemplary embodiments disclosed herein can be adapted to various configurations without departing from the disclosed principles.

The previous description of the disclosed embodiments is provided to enable any person skilled in the art to make or use the disclosed innovations. Various modifications to those embodiments will be readily apparent to those skilled in the art, and the generic principles defined herein may be applied to other embodiments without departing from the spirit or scope of this disclosure. Thus, the claimed inventions are not intended to be limited to the embodiments shown herein, but are to be accorded the full scope consistent with the language of the claims, wherein reference to an element in the singular, such as by use of the article “a” or “an” is not intended to mean “one and only one” unless specifically so stated, but rather “one or more”. All structural and functional equivalents to the elements of the various embodiments described throughout the disclosure that are known or later come to be known to those of ordinary skill in the art are intended to be encompassed by the features described and claimed herein. Moreover, nothing disclosed herein is intended to be dedicated to the public regardless of whether such disclosure is explicitly recited in the claims. No claim element is to be construed under the provisions of 35 USC 112, sixth paragraph, unless the element is expressly recited using the phrase “means for” or “step for”.

Thus, in view of the many possible embodiments to which the disclosed principles can be applied, it should be recognized that the above-described embodiments are only examples and should not be taken as limiting in scope. We therefore reserve all rights to the subject matter disclosed herein, including the right to claim all that comes within the scope and spirit of the foregoing description.

What is claimed:

1. A cooling system, comprising:
a first heat transfer section comprising a liquid, wherein the first heat transfer section comprises a liquid outlet and a liquid inlet, which are connected with outside the first heat transfer section; and
a second heat transfer section comprising refrigerant which is a mixture of liquid refrigerant and gas refrigerant, wherein the second heat transfer section has a closed structure,
wherein the liquid refrigerant is configured to be phase-changed to the gas refrigerant by exchanging heat with a die, and
wherein the gas refrigerant is configured to be phase-changed to the liquid refrigerant by exchanging heat with the liquid of the first heat transfer section.

2. The cooling system according to claim 1, wherein the die is a silicon material on which a processor is fabricated.

3. The cooling system according to claim 1, further comprising:
a printed circuit board (PCB) contacting to a first side the die;
a first thermal interface material (TIM) placed on a second side of the die;
an integrated heat spreader encompassing the PCB, the die, and the first TIM; and
a second TIM placed on the integrated heat spreader,
wherein the second heat transfer section is contacting to the second TIM.

4. A cooling method, comprising:
circulating a liquid through a liquid outlet and a liquid inlet of a first heat transfer section from outside the first heat transfer section to inside first heat transfer section;
circulating a refrigerant, which is a mixture of liquid refrigerant and gas refrigerant, only inside a second heat transfer section having a closed structure;
performing a first phase-change from the liquid refrigerant to the gas refrigerant by exchanging heat with a die; and
performing a second phase-change from the gas refrigerant to the liquid refrigerant by exchanging heat with the liquid of the first heat transfer section.
